(19) United States
(12) Patent Application Publication
(10) Pub. No.: US 2025/0140516 A1
(43) Pub. Date: May 1, 2025

(54) Recipe Creating System, Length Measurement System, and Recipe Creating Method

(71) Applicant: Hitachi High-Tech Corporation, Minato-ku, Tokyo (JP)

(72) Inventors: Hiromi FUJITA, Tokyo (JP); Toshikazu KAWAHARA, Tokyo (JP); Hitoshi SUGAHARA, Tokyo (JP)

(21) Appl. No.: 18/865,765

(22) PCT Filed: May 30, 2022
(86) PCT No.: PCT/JP2022/022018

§ 371 Date: Nov. 14, 2024

(51) Int. Cl. H01J 37/26; H01J 37/22; H01J 37/28

(52) U.S. Cl. CPC H01J 37/265; H01J 37/224; H01J 37/28

(57) ABSTRACT

According to the present invention, a design image based on design data is set for each image acquisition condition, and a length measurement cursor is set in each of the design images. This recipe creating system for creating a recipe in which a procedure for measuring the length of an observed object is described, involves executing: a storage process of storing design data of an observed object including a plurality of layers; a layer-setting process of setting, from among the plurality of layers, at least one layer for each image acquisition condition for the observed object; and a length measurement cursor-setting process of setting a length measurement cursor indicating a length measurement region of the observed object in a design image formed by a design present in the at least one layer set in the setting process.

### TECHNICAL FIELD

The present disclosure relates to a recipe creation system, a measurement system, and a recipe creation method.

### BACKGROUND ART

In order to realize larger scale and higher integration of semiconductor devices, stacking of devices is progressing. As multi-layering progresses in 3D-NAND structures and the like, it becomes necessary to measure deep trenches and deep holes. Therefore, a scanning electron microscope equipped with a plurality of detectors (for example, a detector that detects secondary electrons and a detector that detects backscattered electrons) is proposed (see, for example, Patent Literature 1). The scanning electron microscope of Patent Document 1 includes a plurality of detectors, and thus the SEM images are diversified. For this reason, even at the same measurement position, patterns of a plurality of layers may or may not be observed depending on the SEM image.

### CITATION LIST

### Patent Literature

PTL 1: JP2009-243993A

### SUMMARY OF INVENTION

### Technical Problem

In the device manufacturing process, semiconductor patterns and the like are measured by using a critical dimension scanning electron microscope (CD-SEM) to manage dimensions. In order to measure semiconductor patterns and the like, it is necessary to create a recipe that describes a procedure for the measurement. When creating a recipe on a CD-SEM, it is necessary to move to the measurement coordinate value on a wafer and set the measurement cursor while checking the pattern to be measured (SEM image), so it takes time for creating a recipe on a CD-SEM.

Since creating a recipe on a CD-SEM reduces the operating time of an apparatus, there is an offline recipe creation system that allows CD-SEM recipes to be created offline. In the offline recipe creation system, a recipe for CD-SEM is generated offline (without using an SEM image) by using design data of a semiconductor pattern.

FIG. 11 shows an example of measuring a semiconductor pattern according to a recipe created by an offline recipe creation system in the related art. As illustrated in FIG. 11, first, a recipe for measuring a semiconductor pattern is created in the offline recipe creation system. For example, in the offline recipe creation system, in order to measure a distance between semiconductor patterns, a measurement cursor 1020 is set on a semiconductor pattern 1010 in a design image 1000 based on design data of the semiconductor pattern.

The measurement cursor 1020 is set on an SEM image 2000 captured by a CD-SEM, and the distance between semiconductor patterns 2010 on the SEM image 2000 is measured. Here, a case where a SEM image A and a SEM image B are acquired due to the diversification of SEM images is described. The SEM image A includes only the semiconductor pattern 2010 to be observed, and thus the measurement cursor 1020 can accurately measure the distance between the semiconductor patterns 2010. However, since the SEM image B includes a semiconductor pattern 2020 of another layer in addition to the semiconductor pattern 2010 to be observed, the measurement cursor 1020 overlapping the semiconductor pattern 2020 of the other layer cannot measure the distance between the semiconductor patterns 2010 to be observed.

In this way, when the design image 1000 based on the design data displayed in the offline recipe creation system does not substantially match the SEM image 2000, the measurement cursor 1020 cannot be arranged at an appropriate position.

In this case, it is necessary for the user to correct the measurement cursor in the CD-SEM, and thus labor for correcting the recipe is required. In addition, in an offline recipe creation system in the related art, there is only one type of design image based on design data for which a measurement cursor can be set, whereas there are a plurality of SEM images depending on image acquisition conditions. Therefore, it is difficult to measure a plurality of SEM images with a measurement cursor for one type of design image.

As a result, the disclosure provides a recipe creation system that can set a design image based on design data for each image acquisition condition and set a measurement cursor for each of the plurality of design images.

### Solution to Problem

To solve the above problem, the recipe creation system of the present disclosure is a recipe creation system that creates a recipe describing a procedure for measuring an observation target by a computer system, and this computer system executes a storage process of storing design data of the observation target including a plurality of layers in a storage device; a layer setting process of setting one or more layers from the plurality of layers for each image acquisition condition of the observation target; and a measurement cursor setting process of setting a measurement cursor indicating a measurement area of the observation target in a design image configured with designs existing in the one or more layers set by the setting process.

### Advantageous Effects of Invention

According to the disclosure, a design image based on design data can be set for each image acquisition condition, and a measurement cursor can be set for each of a plurality of design images.

Problems, configurations, and effects other than those described above become clear from the following description of the embodiments.

### BRIEF DESCRIPTION OF DRAWINGS

FIG. 1 is a diagram illustrating the overall configuration of a measurement system of Example 1.

FIG. 2 is a data flow diagram in an offline recipe creation system of Example 1.

FIG. 3 is a flowchart showing a process executed by the offline recipe creation system of Example 1.

FIG. 4 is a diagram illustrating a design layout setting screen of Example 1.

FIG. 5 is a diagram illustrating a layer detail setting screen of Example 1.

FIG. 6 is a diagram illustrating an example in which the offline recipe creation system of Example 1 sets a measurement cursor for a design image.

FIG. 7 is a diagram illustrating an SEM image display screen of Example 2.

FIG. 8 is a diagram illustrating an SEM image display screen of Example 3.

FIG. 9 is a diagram illustrating a configuration of a system including a training system of Example 4.

FIG. 10 is a diagram illustrating a result output of a training system of Example 4.

FIG. 11 is a diagram illustrating an example of measuring a semiconductor pattern according to a recipe created by an offline recipe creation system in the related art.

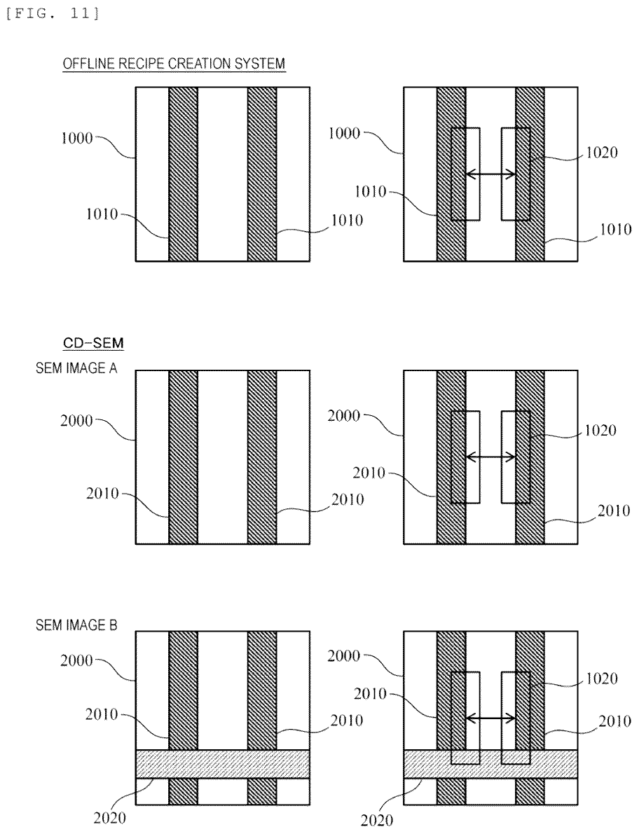

### DESCRIPTION OF EMBODIMENTS

An embodiment of the disclosure is described in detail with reference to the drawings. In the following embodiments, it is certain that the configuration (including steps of flowcharts) is not necessarily essential, except when specifically indicated or when it is considered to be obviously essential in principle. Hereinafter, preferred examples of the disclosure are described with reference to the drawings.

### Example 1

### Configuration of Measurement System 1

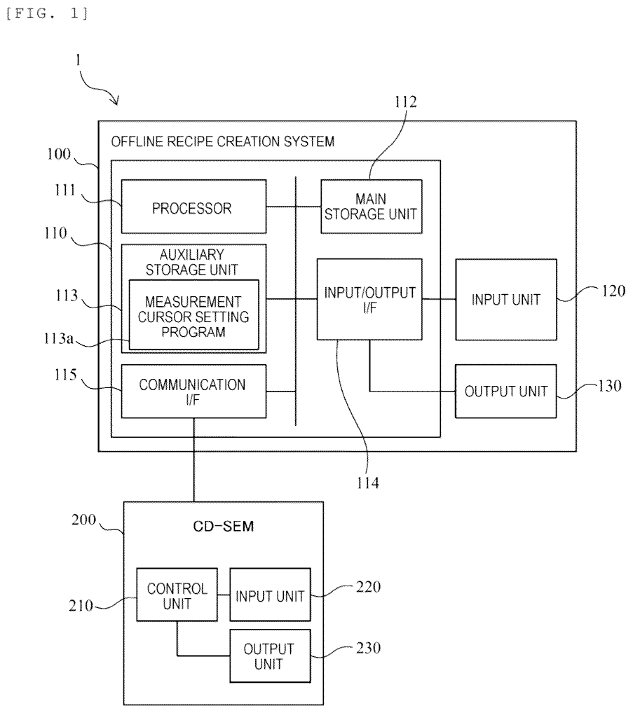

FIG. 1 is a diagram illustrating the overall configuration of a measurement system of Example 1. The configuration of a measurement system 1 is described with reference to FIG. 1. As illustrated in FIG. 1, the measurement system 1 includes an offline recipe creation system 100 and a charged particle beam apparatus (CD-SEM) 200. The offline recipe creation system 100 and the CD-SEM 200 are communicably connected. The offline recipe creation system 100 has a computer system including a processor, a memory, or the like and is an information processing apparatus such as a personal computer, a server, a tablet, or a smartphone. The offline recipe creation system 100 generates a recipe (information describing a procedure of measuring the observation target) of the CD-SEM offline (without using the SEM image). The CD-SEM 200 is an apparatus of measuring a dimension of a fine pattern of a semiconductor and measures a desired locations according to the recipe. The CD-SEM 200 includes a plurality of detectors and can capture images of the observation target under various image acquisition conditions according to the recipe.

### Configuration of Offline Recipe Creation System 100

Next, the configuration of the offline recipe creation system 100 is described. The offline recipe creation system 100 includes a control unit 110, an input unit 120, and an output unit 130. The control unit 110 is a computer system and includes a processor 111, a main storage unit 112, an auxiliary storage unit 113, an input and output interface 114 (hereinafter, interface is abbreviated as I/F), and a communication I/F 115.

The processor 111 is a central processing calculation device that controls the operation of each part of the control unit 110. Examples of the processor 111 includes a central processing unit (CPU), a digital signal processor (DSP), and an application specific integrated circuit (ASIC). The processor 111 loads programs stored in the auxiliary storage unit 113 onto the working area of the main storage unit 112 in an executable manner. The main storage unit 112 stores programs to be executed by the processor 111, data to be processed by the processor, and the like. The main storage unit 112 is a flash memory, a random access memory (RAM), and the like. The auxiliary storage unit 113 stores various programs and various data. The auxiliary storage unit 113 stores various programs such as an operating system (OS) and a measurement cursor setting program 113a. The auxiliary storage unit 113 is a solid state drive device (SSD, Solid State Drive), a hard disk (HDD, Hard Disk Drive) device, and the like. The input unit 120 is, for example, a keyboard or a mouse. The output unit 130 is, for example, a display unit.

It should be noted that the CD-SEM 200 also includes a control unit 210, an input unit 220, and an output unit 230. The control unit 210, the input unit 220, and the output unit 230 of the CD-SEM 200 each are the same as the control unit 110, the input unit 120, and the output unit 130 of the offline recipe creation system 100, and thus the description thereof is omitted.

### Data Flow in Offline Recipe Creation System 100

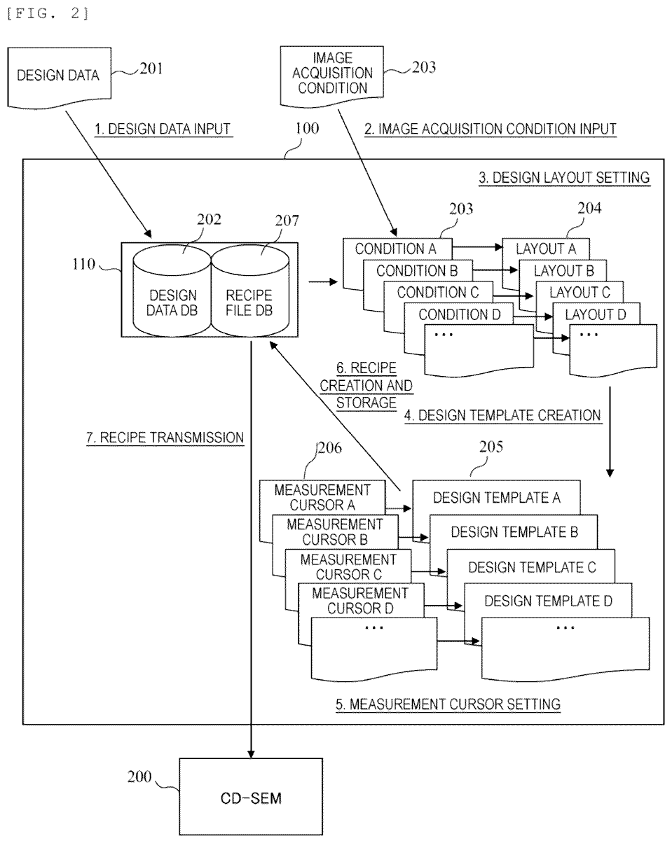

FIG. 2 is a data flow diagram in the offline recipe creation system of Example 1. The flow of data in the offline recipe creation system 100 is described with reference to FIG. 2.

### (1. Design Data Input)

First, the user inputs design data 201 of the observation target (semiconductor pattern) to the offline recipe creation system 100. The design data 201 is, for example, computer-aided design (CAD) data. The input design data 201 is registered in design data DB 202. The design data DB 202 is stored, for example, in the auxiliary storage unit 113.

### (2. Image Acquisition Condition Input)

Next, the user inputs one or a plurality of image acquisition conditions 203 for capturing an image of the observation target with the CD-SEM 200. The image acquisition conditions include, for example, the imaging position (coordinate values), imaging range, imaging magnification, and information indicating the detector to be used.

### (3. Design Layout Setting)

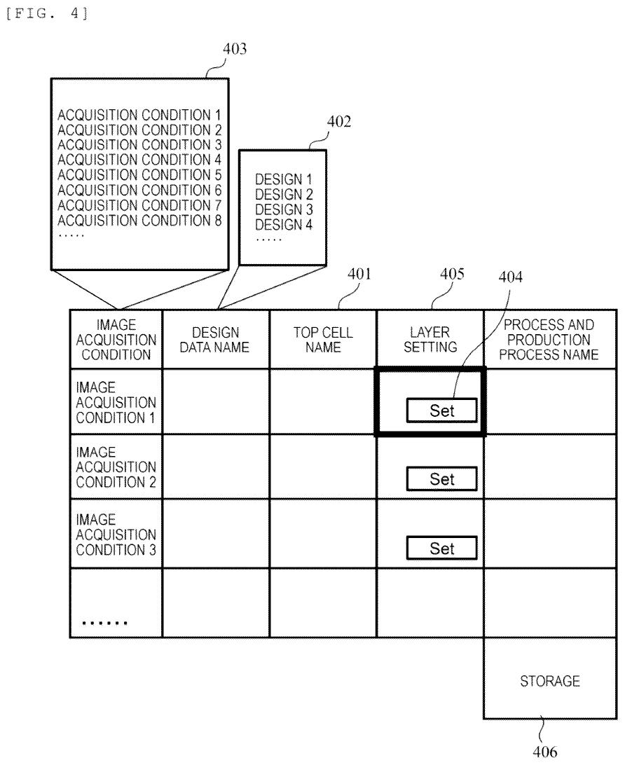

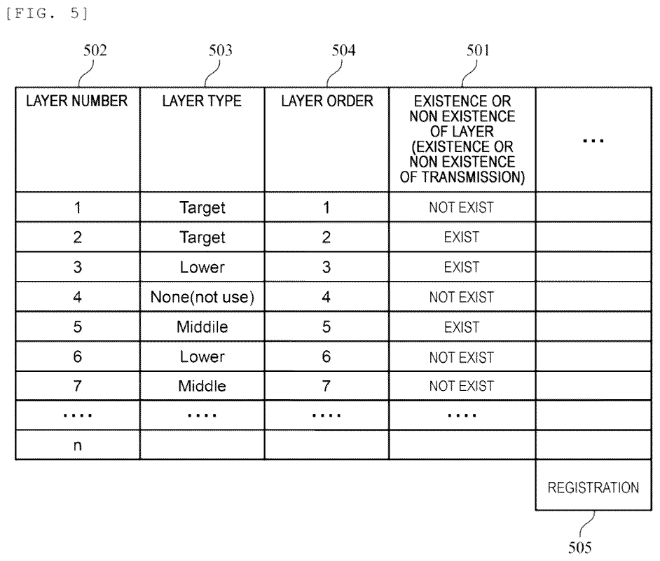

Next, the user sets a design layout 204 for each of the input image acquisition conditions 203. The setting of the design layout 204 is described in detail in FIGS. 4 and 5 below.

### (4. Design Template Creation)

When the design layout 204 is set for each image acquisition condition 203, the offline recipe creation system 100 creates a design template 205. The design template 205 is data that combines designs provided in one or a plurality of layers selected by the user from one or a plurality of layers that configures the design data.

### (5. Measurement Cursor Setting)

When a design template is created, the offline recipe creation system 100 sets a measurement cursor 206 for each of the design templates 205. The measurement cursor indicates the measurement area (a size in the X direction and a size in the Y direction) of the SEM image captured by the CD-SEM 200.

### (6. Recipe Creation and Storage)

The offline recipe creation system 100 creates a recipe in which the measurement cursor 206 is set in the design template 205 and stores it in the recipe file DB 207. The recipe file DB 207 is stored in, for example, the auxiliary storage unit 113.

### (7. Recipe Transmission)

The offline recipe creation system 100 transmits the recipe stored in the recipe file DB 207 to the CD-SEM 200.

The CD-SEM 200 captures an image of the observation target according to the image acquisition conditions 203 defined in the recipe and measures the observation target in a measurement range indicated by the measurement cursor defined in the recipe.

### Data Process of Offline Recipe Creation System 100 (Recipe Creation Method)

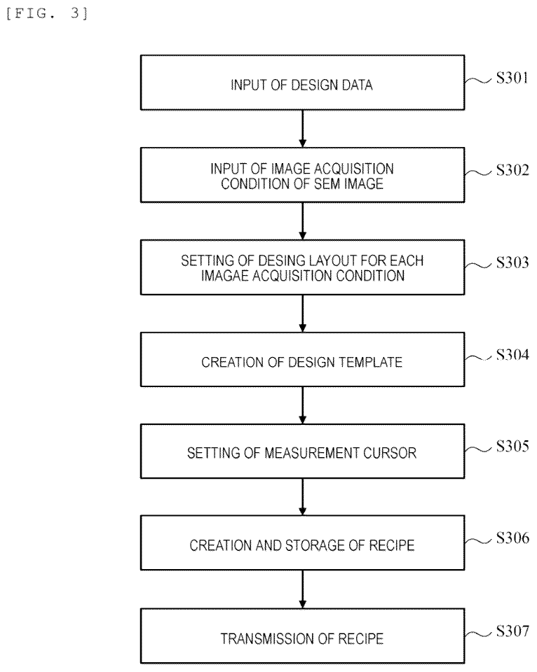

FIG. 3 is a flowchart showing a process executed by the offline recipe creation system of Example 1. The data process executed in the offline recipe creation system 100 is described with reference to FIG. 3. Each step of the flowchart illustrated in FIG. 3 is executed, for example, by the processor 111 of the control unit 110 of the offline recipe creation system 100 executing the measurement cursor setting program 113a stored in the auxiliary storage unit 113. It should be noted that “1. Design Data Input”, “2. Image Acquisition Condition Input”, “3. Design Layout Setting”, “4. Design Template Creation”, “5. Measurement Cursor Setting”, “6. Recipe Creation and Storage”, and “7. Recipe Transmission” in FIG. 2 correspond to steps S301 to 307 in FIG. 3, respectively.

### (Step S301: Input of Design Data)

The user inputs design data (layout file) the observation target (for example, a semiconductor pattern) to the offline recipe creation system 100. This design data (layout file) is data that is configured with a plurality of layers. The offline recipe creation system 100 can store a plurality of pieces of design data in the design data DB 202.

### (Step S302: Input of Image Acquisition Condition of SEM Image)

Next, the user inputs the image acquisition conditions for the SEM images. The coordinate values and imaging magnification of the image acquisition conditions may be input by using a file in which the coordinate values and imaging magnification are listed in pairs.

### (Step S303: Set of Design Layout for Each Image Acquisition Condition)

Next, the user sets the design layout for each image acquisition condition for the SEM images. Specifically, the user sets the design layout for each image acquisition condition for the SEM images on the design layout setting screen (see FIG. 4). First, the user sets a design data name 402 for each image acquisition condition. Also, the user selects an image acquisition condition 403 from a pull-down menu. The image acquisition condition that the user has set in advance are stored as templates. It should be noted that the image acquisition conditions may be input each time on the design layout screen. Next, the user sets a top cell name 401 of the design layout that configures the observation target. In the design layout, patterns are configured as cells, and the top cell is configured with a plurality of cells. It is also possible to set a different design data name and a top cell name for each image acquisition condition.

Also, the user sets one or a plurality of layers for each image acquisition condition. By selecting a layer setting button 404 illustrated in FIG. 4, the layer detail setting screen of FIG. 5 is displayed. On the layer detail setting screen, the user imagines a design that can be observed when the CD-SEM 200 captures images of the observation target under the image acquisition conditions and selects the layer in which the design is to be located. All layer numbers 502 provided in the top cell are displayed on the layer detail setting screen. The user sets a layer type 503 and a layer order 504 for each layer. For example, in the layer type 503, the user sets a layer having the design of the observation target as “Target”, sets a layer having a design that can be observed as “Lower”, “Middle”, or “Reference”, and sets a layer having a design that cannot be observed as “None (not use)”. In addition, in the layer order 504, the user also sets a number from the top layer. Furthermore, in existence or non existence of layer 501, the user sets the layer having the design that can be observed as “Exist” and sets a layer having a design that cannot be observed as “Not Exist”.

After the various settings are completed, the user selects a registration button 505 to register the details of the layer for each image acquisition condition. When the registration button 505 is selected, the design layout setting screen (FIG. 4) is displayed. Here, when a storage button 406 is selected, various pieces of information set for each image acquisition condition are stored. Images observed for each image acquisition condition are different, the user repeats the layer setting for each image acquisition condition.

### (Step S304: Creation of Design Template)

The offline recipe creation system 100 creates the design template based on the image acquisition condition and the design layout setting. A design template is a file that represents a design image configured with designs provided in layers set in the design layout settings, with designated coordinate values and imaging magnification.

### (Step S305: Setting of Measurement Cursor)

The offline recipe creation system 100 sets the measurement cursor based on the created design template. The computer system automatically sets a measurement cursor from the design image based on the design template, avoiding designs other than “Target”. That is, in the embodiment, the measurement cursor can be set according to the design image for each image acquisition condition.

### (Step S306: Creation and Storage of Recipe)

The processes of steps S305 and S306 are repeated for each design template to set a measurement cursor for each design template. Then, the computer system creates a recipe based on the image acquisition conditions or the measurement cursor set in the design template. The design template and the recipe are stored in the recipe file DB 207.

### (Step S307: Transmission of Recipe)

The offline recipe creation system 100 transmits the stored recipe to the CD-SEM 200. The CD-SEM 200 selects and executes the received recipe.

### (Setting Example of Measurement Cursor)

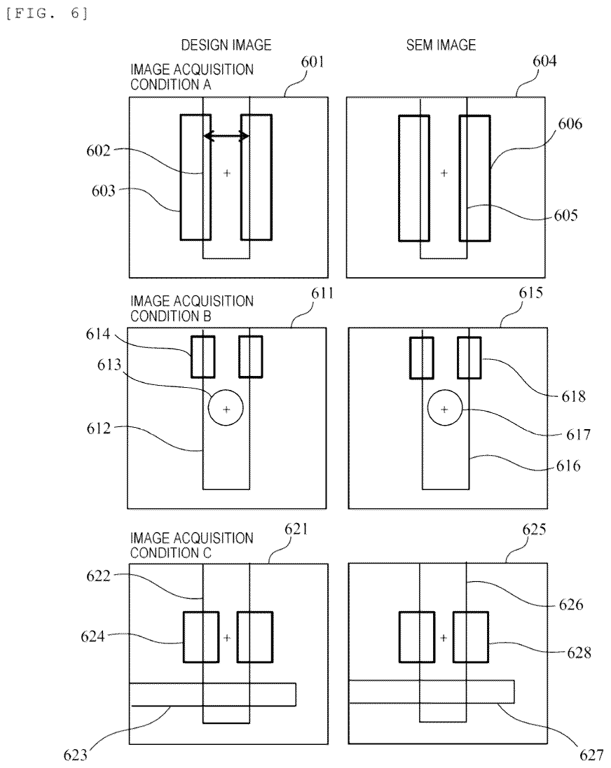

FIG. 6 is a diagram illustrating an example in which the offline recipe creation system of Example 1 sets a measurement cursor for a design image. A setting example of the measurement cursor is described with reference to FIG. 6.

A design image 601 based on design data set under an image acquisition condition A includes a line pattern 602. The offline recipe creation system 100 sets the measurement cursor 603 for measuring a width of the line pattern 602 based on the design template set for an image acquisition condition 1.

A line pattern 605 is provided in a SEM image 604 captured by imaging the observation target by the CD-SEM 200 under the image acquisition condition A. A measurement cursor 606 is set for the line pattern 605 of the SEM image 604 and thus the width of the line pattern 605 can be accurately measured.

A design image 611 based on design data set under an image acquisition condition B is a pattern in which a line pattern 612 and a hole 613 of a lower layer thereof are overlapped (overlayed). The offline recipe creation system 100 sets a measurement cursor 614 for measuring a width of the line pattern 612 with avoiding the hole 613, based on the design template set under the image acquisition condition B.

A line pattern 616 and a hole 617 are provided in a SEM image 615 captured by imaging the observation target by the CD-SEM 200 under the image acquisition condition B. A measurement cursor 618 is set on the line pattern 616 of the SEM image 615 with avoiding the hole 617, and thus the width of the line pattern 616 can be accurately measured.

A design image 621 based on the design data set under an image acquisition condition C is a pattern including a vertical line pattern 622 and a horizontal line pattern 623 of a lower layer or an upper layer thereof. The offline recipe creation system 100 sets a measurement cursor 624 for measuring a width of the vertical line pattern 622 so as not to include the horizontal line pattern 623 based on the design template set under the image acquisition condition C.

A vertical line pattern 626 and a horizontal line pattern 627 are included in a SEM image 625 captured by imaging the observation target by the CD-SEM 200 under an image acquisition condition 3. A measurement cursor 628 is set in the vertical line pattern 626 of the SEM image 625 so as not to include the horizontal line pattern 627, and thus the width of the vertical line pattern 626 can be accurately measured.

### (Effect of Example 1)

In Example 1, the measurement cursor can be set for each design image by setting the design image based on the design data for each image acquisition condition. Therefore, the measurement cursor can be set in accordance with various SEM images acquired by the CD-SEM 200. As a result, it is possible to reduce cases where the design image does not match the SEM image, and it is not necessary to correct the measurement cursor while viewing the SEM image on the CD-SEM 200.

The offline recipe creation system 100 can display the design image and the measurement cursor on one screen. Therefore, when manually setting the measurement cursor, the user can easily set the measurement cursor.

Also, the user (expert) can select an appropriate layer from the plurality of layers that configure the design data for each image acquisition condition and set the design image.

Also, since the user can select the design of the observation target in the layer type 503, the offline recipe creation system 100 can set the measurement cursor with avoiding other than the design of the observation target.

### Example 2

The CD-SEM 200 of Example 2 receives the design template from the offline recipe creation system 100 and displays the design image based on the received design template. In addition, in Example 2, the design image is displayed in a manner of being overlayed on the SEM image captured by the CD-SEM 200.

Next, the procedure in which the CD-SEM 200 of Example 2 overlays the design image on the SEM image is described.

### (1. Recipe Selection by CD-SEM 200)

The CD-SEM 200 stores the recipe received from the offline recipe creation system 100 (see Step S307 of FIG. 3). The user selects the recipe received from the offline recipe creation system 100 with the CD-SEM 200.

### (2. Execution of Recipe)

Also, the CD-SEM 200 executes the selected recipe. The CD-SEM 200 captures the observation target according to the image acquisition condition set by the recipe and measures the observation target of the SEM image with the measurement cursor set by the recipe.

### (3. Checking of Execution Result (Overlay Display of Design))

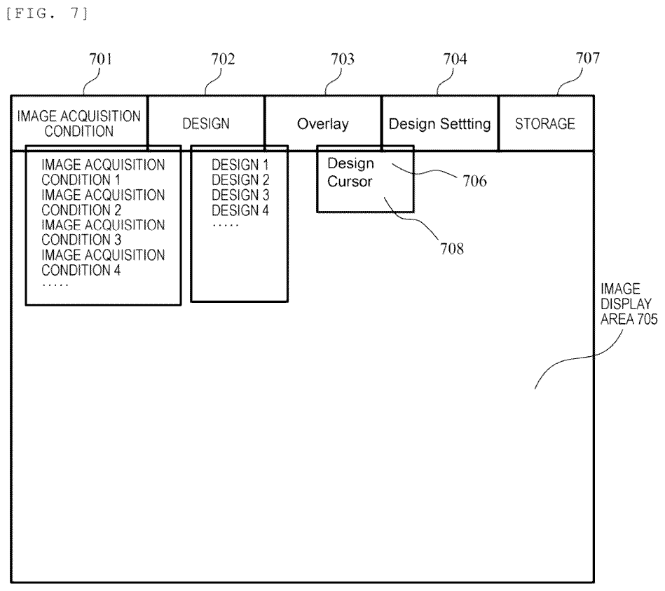

When the execution of the recipe is completed, the user visually checks whether the observation target can be measured with the measurement cursor set by the design image based on the design template on the SEM image display screen (FIG. 7). The SEM image display screen (FIG. 7) is displayed on the output unit (display unit) 230 of the CD-SEM 200. When an image acquisition condition 701 is selected by the SEM image display screen, a SEM image acquired under the image acquisition condition selected in an image display area 705 is displayed.

Also, the CD-SEM 200 of Example 2 displays the design image in a manner of being overlayed on the SEM image. In the operation method, when a design image is selected with a pull-down menu or the like of Design 702 of a SEM image display screen (FIG. 7), and Design 706 is selected with a pull-down menu or the like of Overlay 703, the design image is displayed on the SEM image in a manner of being overlayed on the image display area 705. In addition, when Cursor 708 is selected with the pull-down menu of Overlay 703, the measurement cursor is displayed in a manner of being overlayed on the SEM image in the image display area 705. It should be noted that Design 706 and Cursor 708 both can be selected at the same time, and the design image and the measurement cursor both can be displayed in an overlayed manner on the SEM image at the same time.

### (Effect of Example 2)

In Example 2, since the design image and the measurement cursor can be display in a manner of being overlayed on the SEM image, it becomes easy to check the position of the measurement cursor. Without this display function, the display of the measurement cursor and the SEM image are deviated to cause a measurement error, the original design image cannot be checked on the CD-SEM 200. Therefore, even to correct the original design image, the screen has to be checked by returning to the offline recipe creation system, and thus it takes time for correction. It is possible to check where the deviation is by using the overlay image and correct the design to better match the SEM image, thereby shortening the recipe creation time.

### Example 3

The CD-SEM 200 of Example 3 can change the design image in accordance with the SEM image. In Example 3, when the SEM image and the design image displayed in the image display area 705 (see Example 2) are deviated to cause a measurement error, the CD-SEM 200 can change the design image with reference to the SEM image.

### (1. Display of Design Image)

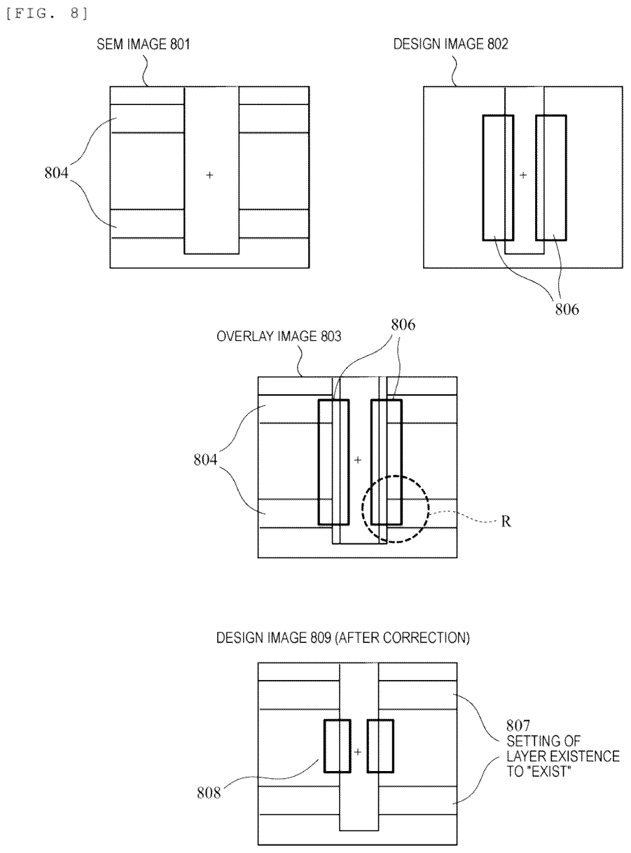

The CD-SEM 200 of Example 3 displays a SEM image 801 and a design image 802 on the output unit (display unit) 230. Two horizontal line patterns 804 that do not exist in the design image 802 exist in the SEM image 801. Also, similarly to Example 2, the CD-SEM 200 of Example 3 displays an overlay image 803 obtained by overlaying the design image on the SEM image. It should be noted that a measurement cursor 806 is also overlayed on the overlay image 803. The horizontal line pattern 804 of a layer that is not set in the design image 802 exists in the SEM image 801. Therefore, in an area R in FIG. 8, the measurement cursor 806 is laid on the horizontal line pattern 804 to cause a measurement error. Therefore, in the CD-SEM 200, it is necessary to reset the position and range of the measurement cursor 806 with reference to the SEM image 801 so that the measurement cursor 806 is not laid on the horizontal line pattern 804.

### (2. Correction of Design Image or Measurement Cursor)

The user corrects the design image in accordance with the SEM image in the CD-SEM 200. For example, when a design setting button 704 of FIG. 7 is selected, the same screen as the design layout setting screen (FIG. 4) displayed in the offline recipe creation system 100 is displayed on the CD-SEM 200. When the image acquisition condition 403 of the SEM image is selected on the screen, and the layer setting button 404 of a layer setting 405 is selected, the layer detail setting screen (FIG. 5) is displayed on the CD-SEM 200. Here, the user selects the layer number 502 corresponding to two horizontal lines shown in the SEM image and sets “Exist” in the existence or non existence of layer 501. Then, the user selects the registration button 505, returns to the design layout setting screen (FIG. 3), selects the storage button 406, and performs correction.

Here, when the storage button 406 is selected, the design template managed by the offline recipe creation system 100 is corrected similarly. The design template managed by the offline recipe creation system 100 and the design template managed by the CD-SEM 200 are synchronized to have the same content.

### (Effect of Example 3)

As described above, in Example 3, the user can correct the existence or non existence of layer 501 on the CD-SEM 200 and can display the design image after correction. Also, the user can again select Design 702 on the image display screen (FIG. 7), set display of Design 706 in Overlay 703 to an On state, and display a design image 809 after correction.

Also, in accordance with the design image after correction, when a measurement cursor 808 corrected so as not to be laid on a horizontal pattern 807 is also stored by pushing a storage button 707 on the apparatus, the measurement cursor of the recipe can be stored on the offline recipe creation system 100 in a synchronized manner, and thus the creation time of the recipe can be significantly reduced.

In Example 3, the correction of the design image and the correction of the measurement cursor can be performed on the CD-SEM 200.

### Example 4

In Examples 2 and 3, the design layout setting for each image acquisition condition is performed by the user. In Example 4, the system trained by AI automatically set the design image based on the image acquisition condition. In Example 1, a knowledgeable user who can predict the SEM image to be acquired based on the image acquisition conditions sets the design image for each image acquisition condition, but this function causes the AI to learn the skills of an expert, so that anyone can set the design image.

### (1. Training of Training System)

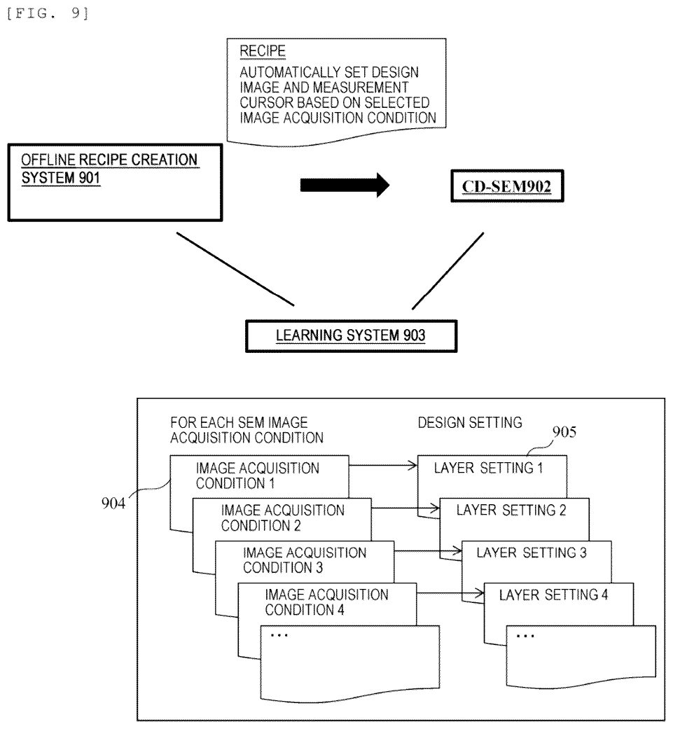

As illustrated in FIG. 9, an offline recipe creation system 901 and the CD-SEM 200 are connected to a training system 903 via a network. In the offline recipe creation system 901, a design setting 905 of the existence or non existence of layer is performed for each image acquisition condition 904 in the setting of the design layout for each image acquisition condition. This information (training data) is input to the training system 903.

Also, the correction content of the design setting 905 of the existence or non existence of layer for each image acquisition condition 904 performed by the CD-SEM 200 is input to the training system 903. The design setting 905 may be corrected in the offline recipe creation system 901, the correction content may be input to the training system 903. Accordingly, the design setting 905 for each image acquisition condition 904 better matches the SEM image, the accuracy enhances. This information is repeated and is input to the training system 903, so that the training system 903 can be additionally trained with the design setting 905 for each image acquisition condition.

### (2. Automatic Design Setting in Offline Recipe Creation System)

The user selects the image acquisition condition. The training system 903 acquires and automatically set the design image matching the image acquisition condition based on the selected image acquisition condition. At time, the measurement cursor may be set for the design image. All items that can be set on the design layout setting screen (FIG. 3) for each image acquisition condition are targets of the design image to be set.

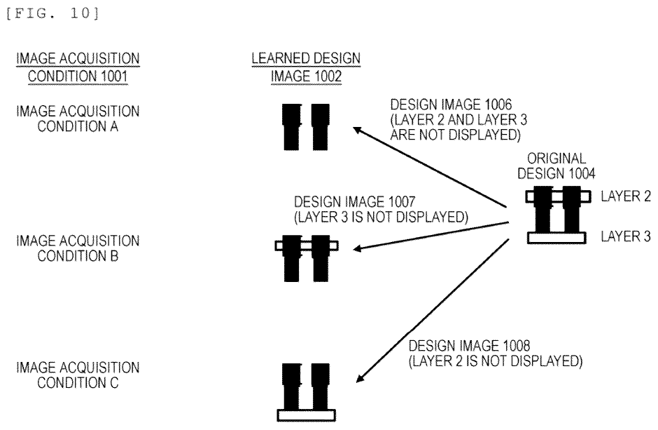

As illustrated in FIG. 10, when an image acquisition condition 1001 is input to the offline recipe creation system 901, the training system 903 can output a design image 1002 based on the image acquisition condition 1001. For example, when the user selects the image acquisition condition A, the offline recipe creation system 901 automatically sets a design image 1006 that does not include the patterns of a layer 2 and a layer 3 from a layer provided in an original design 1004. Also, when the user selects the image acquisition condition B, the offline recipe creation system 901 automatically sets a design image 1007 that does not include the pattern of the layer 3 from the layer provided in the original design 1004. Also, when the user selects the image acquisition condition C, the offline recipe creation system 901 automatically sets a design image 1008 that does not include the pattern of the layer 2 from the layer provided in the original design 1004.

### (Effect of Example 4)

Therefore, the layer setting for each image acquisition condition which only an expert user can perform becomes unnecessary, and thus the efficiency of recipe creation is significantly improved.

It should be noted that the disclosure is not limited to the above-mentioned examples and includes various modifications. The above-mentioned examples have been described in detail to clearly explain the disclosure and are not necessarily limited to those having all of the described configurations. In addition, a part of the configuration of one example can be replaced with the configuration of another example, and the configuration of an example can be added to the configuration of the other example. Also, a part of the configuration of each example can be added to, deleted from, or replaced with another configuration.

For example, in Example 1, an example was described in which the offline recipe creation system 100 automatically sets a measurement cursor for a design image, but the measurement cursor may be set manually by the user. In this case, the offline recipe creation system 100 may determine whether the position of the measurement cursor set manually is appropriate and issue a warning or the like.

### REFERENCE SIGNS LIST

1: measurement system
100: offline recipe creation system
110: control unit
111: processor
112: main storage unit
113: auxiliary storage unit
114: input and output I/F
115: communication I/F
120: input unit
130: output unit
200: CD-SEM
201: design data
202: design data DB
203: image acquisition condition
204: design layout
205: design template
206: measurement cursor, recipe file DB
210: control unit
220: input unit
230: output unit

1. A recipe creation system that creates a recipe describing a procedure of measuring an observation target by a computer system,
wherein the computer system executes:
a storage process of storing design data of the observation target including a plurality of layers in a storage device;
a layer setting process of setting one or more layers from the plurality of layers for each image acquisition condition of the observation target; and
a measurement cursor setting process of setting a measurement cursor indicating a measurement area of the observation target in a design image configured with designs existing in the one or more layers set by the layer setting process.

2. The recipe creation system according to claim 1, wherein the computer system further executes:
a display process of displaying the design image and the measurement cursor on one screen.

3. The recipe creation system according to claim 1, wherein the layer setting process includes a process of setting one or more layers from the plurality of layers according to selection of a user.

4. The recipe creation system according to claim 1, wherein the layer setting process include a process of setting one or more layers from the plurality of layers based on the image acquisition condition.

5. The recipe creation system according to claim 1, wherein the computer system further executes:
a layer type setting process of setting a layer type indicating whether each of the plurality of layers is the observation target, and
the measurement cursor setting process includes a process of setting the measurement cursor with avoiding a design of a layer other than the layer set as the observation target by the layer type setting process in the design image.

6. The recipe creation system according to claim 1, wherein the computer system further executes:
a transmission process of transmitting a recipe including the image acquisition condition and the measurement cursor to a charged particle beam apparatus that measures the observation target according to the recipe.

7. A measurement system comprising:
a recipe creation system that creates a recipe describing a procedure of measuring an observation target by a first computer system; and
a charged particle beam apparatus that executes the recipe by a second computer system and measures the observation target,
wherein the first computer system includes
a storage process of storing design data of the observation target including a plurality of layers in a storage device;
a layer setting process of setting one or more layers from the plurality of layers for each image acquisition condition of the observation target; and
a measurement cursor setting process of setting a measurement cursor indicating a measurement area of the observation target in a design image configured with designs existing in the one or more layers set by the layer setting process, and
the second computer system executes:
a reception process of receiving the design image; and
a display process of displaying a SEM image captured by imaging the measurement area indicated by the measurement cursor and the design image received by the reception process.

8. The measurement system according to claim 7, wherein the display process includes a process of displaying the measurement cursor in a manner of being overlapped with the SEM image.

9. The measurement system according to claim 7, wherein the second computer system further executes:
a correction process of correcting the measurement cursor on the SEM image displayed by the display process.

10. The measurement system according to claim 7, further comprising:
a training system that is trained by using training data including the image acquisition condition and one or more layers set under the image acquisition condition,
wherein the training system executes the layer setting process of setting one or more layers from the plurality of layers for each image acquisition condition of the observation target.

11. The measurement system according to claim 10, wherein the first computer system or the second computer system further executes:
a layer correction process of correcting the one or more layers set under the image acquisition condition, and
the training system performs additional training by using training data including the image acquisition condition and the one or more layers corrected by the layer correction process.

12. A recipe creation method of creating a recipe describing a procedure of measuring an observation target, the method comprising:
storing design data of the observation target including a plurality of layers in a storage device;
setting one or more layers from the plurality of layers for each image acquisition condition of the observation target;
setting a measurement cursor indicating a measurement area of the observation target to a design image configured by a design existing in the one or more set layers; and
creating a recipe including the image acquisition condition and the set measurement cursor.

13. The recipe creation method according to claim 12, further comprising:
displaying the design image and the measurement cursor on one screen.

14. The recipe creation method according to claim 12, wherein the setting of the one or more layers includes setting one or more layers from the plurality of layers according to selection of a user.

15. The recipe creation method according to claim 12, wherein the setting of the one or more layers includes setting one or more layers from the plurality of layers based on the image acquisition condition.

16. The recipe creation method according to claim 12, further comprising:
setting a layer type indicating whether each of the plurality of layers is the observation target, and
the setting of the measurement cursor includes setting the measurement cursor with avoiding a design of a layer other than the layer set as the observation target in the design image.

17. The recipe creation method according to claim 12, further comprising:
transmitting the recipe including the image acquisition condition and the measurement cursor to a charged particle beam apparatus that measures the observation target according to the recipe.
